(19) United States
(12) Patent Application Publication
(10) Pub. No.: US 2024/0389245 A1
(43) Pub. Date: Nov. 21, 2024

(54) FOLDABLE DISPLAY DEVICE

(71) Applicant: SAMSUNG DISPLAY CO., LTD., YONGIN-SI (KR)

(72) Inventors: YOUNGMYUNG LEE, YONGIN-SI (KR); JONG-NAM LEE, YONGIN-SI (KR); JINHYUK PARK, YONGIN-SI (KR)

(21) Appl. No.: 18/630,039

(22) Filed: Apr. 9, 2024

(30) Foreign Application Priority Data
May 15, 2023 (KR) 10-2023-0062466

(51) Int. Cl. H05K 5/02

(52) U.S. Cl. CPC H05K 5/02

(57) ABSTRACT

A display device includes a display panel including a non-folding area and a foldable area adjacent to the non-folding area, a support member disposed on the display panel and including a flat part overlapping the non-folding area a plurality of first segmental elements overlapping the foldable area, and a plurality of second segmental elements overlapping the foldable area and respectively coupled to the plurality of first segmental elements and a base film disposed on one surface of each of the plurality of first segmental elements and the plurality of second segmental elements.

### CROSS-REFERENCE TO RELATED APPLICATION

This application claims priority under 35 U.S.C. § 119 to Korean Patent Application No. 10-2023-0062466, filed on May 15, 2023, which is hereby incorporated by reference for all purposes as if fully set forth herein.

### TECHNICAL FIELD

Embodiments of the present invention relate to a display device, and more particularly, to a foldable display device.

### DISCUSSION OF THE RELATED ART

Recently, a flexible display device that can be deformed into various shapes has been under development. Unlike a flat panel display, a flexible display device may be folded, bent, or rolled like paper. The flexible display device may be easy to carry and increase user convenience.

Recently, among flexible display devices, a foldable display device may have high demand. The foldable display device may be repeatedly folded and unfolded. Typically, the foldable display device may include a display panel including flexible characteristics and a support member that is disposed on the bottom surface of the display panel. The support member has a relatively large rigidity and thus may prevent deformation of the display panel due to a user's touch or the like.

### SUMMARY

According to an embodiment of the present invention a display device includes a display panel including a non-folding area and a foldable area adjacent to the non-folding area, a support member disposed on the display panel and including a flat part overlapping the non-folding area, a plurality of first segmental elements overlapping the foldable area, and a plurality of second segmental elements overlapping the foldable area and respectively coupled to the plurality of first segmental elements and a base film disposed on one surface of each of the plurality of first segmental elements and the plurality of second segmental elements.

In an embodiment of the present invention each of the plurality of first segmental elements includes a plurality of first protrusions protruding from a first surface of each of the plurality of first segmental elements and a plurality of first depressions depressed from a second surface opposite to the first surface of each of the plurality of first segmental elements and wherein each of the plurality of second segmental elements includes a plurality of second protrusions protruding from a first surface of each of the plurality of second segmental elements, and a plurality of second depressions depressed from a second surface of each of the plurality of second segmental elements opposite to the first surface.

In an embodiment of the present invention the plurality of first segmental elements and the plurality of second segmental elements are alternately arranged.

In an embodiment of the present invention the first protrusions of a first segmental element among the plurality of first segmental elements are coupled to the second depressions of an adjacent second segmental element of the plurality of second segmental elements, respectively, and wherein the first depressions of the first segmental element are coupled to the second protrusions of another adjacent second segmental element of the plurality of second segmental elements respectively.

In an embodiment of the present invention an end of each of the first protrusions and the second protrusions has a circular shape, and a part of each of the first depressions and the second depressions respectively contacting the end of each of the first protrusions and the second protrusions has a rounded shape.

In an embodiment of the present invention an end of each of the first protrusions and the second protrusions has a rectangular shape, and a part of each of the first depressions and the second depressions respectively contacting the end of each of the first protrusions and second protrusions has a rectangular shape.

In an embodiment of the present invention the end of each of the first protrusions and the second protrusions is asymmetrical with respect to a center line passing through centers of the corresponding first protrusions and second protrusions.

In an embodiment of the present invention the base film includes a silicon-based material.

In an embodiment of the present invention the base film contacts first surfaces of the plurality of first segmental elements and first surfaces of the plurality of second segmental elements facing the display panel.

In an embodiment of the present invention the base film contacts a second surface opposite to a first surface of each of the plurality of first segmental elements and the plurality of second segmental elements wherein the first surface faces the display panel.

In an embodiment of the present invention support member includes metal or fiber reinforced plastic.

According to an embodiment of the present invention a display device includes: a display panel including a non-folding area and a foldable area adjacent to the non-folding area, a support member disposed under the display panel and including: a flat part overlapping the non-folding area, a plurality of first segmental elements overlapping the foldable area and including a plurality of first protrusions protruding from first surfaces of the plurality of first segmental elements and having different lengths from each other in a first direction and a plurality of second segmental elements overlapping the foldable area and alternately arranged with the plurality of first segmental elements along the first direction wherein the plurality of second segmental elements includes a plurality of second protrusions protruding from a first surface of the plurality of second segmental elements and having different lengths from each other in a first direction wherein the plurality of second segmental elements are respectively coupled to the plurality of first segmental elements and a base film disposed on each of the plurality of first segmental elements and the plurality of second segmental elements.

In an embodiment of the present invention each of the plurality of first segmental elements further includes a plurality of first depressions depressed from a second surface opposite to the first surface of each of the plurality of first segmental elements and wherein each of the plurality of second segmental elements further includes a plurality of second depressions depressed from a second surface opposite to the first surface of each of the plurality of second segmental elements.

In an embodiment of the present invention the first protrusions of a first segmental element among the plurality of first segmental elements are male and female coupled to the second depressions of an adjacent second segmental element of the plurality of second segmental elements respectively, and wherein the first depressions of the first segmental element are male and female coupled to the second protrusions of another adjacent second segmental element of the plurality of second segmental elements respectively.

In an embodiment of the present invention a length, in the first direction of each of the first protrusions overlapping a center of the foldable area is smaller than a length, in the first direction of each of the first protrusions overlapping an edge of the foldable area, and wherein a length, in the first direction of each of second protrusions overlapping the center of the foldable area is smaller than a length, in the first direction of each of the second protrusions overlapping the edge of the foldable area.

In an embodiment of the present invention each of the first protrusions includes a first neck end and a first end, wherein the first neck end is spaced apart from the first surface of the corresponding first segmental element and the first end extends from the first neck end, and wherein each of the second protrusions includes a second neck end and second end, wherein the second neck end is spaced from the first surface of the corresponding second segmental elements and the second end extends from the second neck end.

In an embodiment of the present invention the first surface of each of the first segmental elements contacts or is spaced apart from the second surface of an adjacent second segmental element of the plurality of second segmental elements and wherein the second surface of each of the first segmental elements contacts or is spaced apart from the first surface of another adjacent second segmental element of the plurality of second segmental elements.

In an embodiment of the present invention the first surface of each of the first segmental elements contacts the second surface of the adjacent second segmental element of the plurality of second segmental elements and the second surface of each of the first segmental elements contacts the first surface of the other adjacent second segmental element wherein the first neck end of each of the first segmental elements is spaced apart from the adjacent second segmental element and overlaps the adjacent second segmental element in a second direction intersecting the first direction and wherein the second neck end of each of the second segmental elements is spaced apart from an adjacent first segmental element and overlaps the adjacent first segmental element in the second direction intersecting the first direction.

In an embodiment of the present invention a length, in the first direction of the first neck end overlapping a center of the foldable area is smaller than a length, in the first direction, of the first neck end overlapping an edge of the foldable area, and wherein a length, in the first direction of the second neck end overlapping the center of the foldable area is smaller than a length, in the first direction of the second neck end overlapping the edge of the foldable area.

In an embodiment of the present invention each of the plurality of first segmental elements and the plurality of second segmental elements extends in a second direction intersecting the first direction.

### BRIEF DESCRIPTION OF THE DRAWINGS

The above and other features of the present invention will become more apparent by describing in detail embodiments thereof with reference to the attached drawings, in which:

FIG. 1 is a perspective view illustrating a display device according to an embodiment of the present invention.

FIG. 2 is a side view illustrating an example of a folded state of the display device of FIG. 1.

FIG. 3 is a side view illustrating an example of a folded state of the display device of FIG. 1.

FIG. 4 is a cross-sectional view taken along line I-I′ line of FIG. 1.

FIG. 5 is an enlarged cross-sectional view of area A of FIG. 4.

FIG. 6 is an enlarged plan view of a plurality of segmental elements of FIG. 4.

FIG. 7 is a plan view illustrating an example of a plurality of segmental elements of FIG. 4 in an unfolded state of the display device of FIG. 4.

FIG. 8 is a plan view illustrating an example of a plurality of segmental elements of FIG. 4 in a folded state of the display device of FIG. 4.

FIG. 9 is a plan view illustrating an example of a plurality of segmental elements of FIG. 4 in a folded state of the display device of FIG. 4.

FIG. 10 is a cross-sectional view illustrating an example of first segmental elements, second segmental elements and a base film of FIG. 4.

FIG. 11 is a cross-sectional view illustrating an example of first segmental elements, second segmental elements and a base film of FIG. 4.

FIG. 12 is a plan view illustrating an example of first segmental elements and second segmental elements of FIG. 4.

FIG. 13 is a plan view illustrating an example of first segmental elements and second segmental elements of FIG. 4.

FIG. 14 is a plan view illustrating an example of first segmental elements and second segmental elements of FIG. 4.

FIG. 15 is a plan view illustrating an example of first segmental elements and second segmental elements of FIG. 4.

### DETAILED DESCRIPTION OF THE EMBODIMENTS

Hereinafter, display devices in accordance with embodiments of the present invention will be described in more detail with reference to the accompanying drawings. The same reference numerals are used for the same components in the drawings and specification, and redundant descriptions of the same components may be omitted or briefly discussed.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

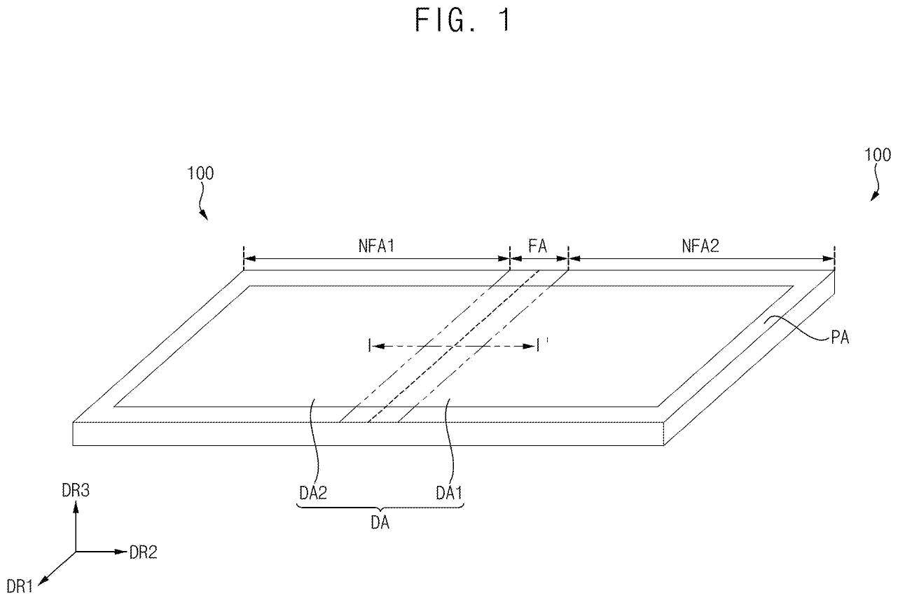

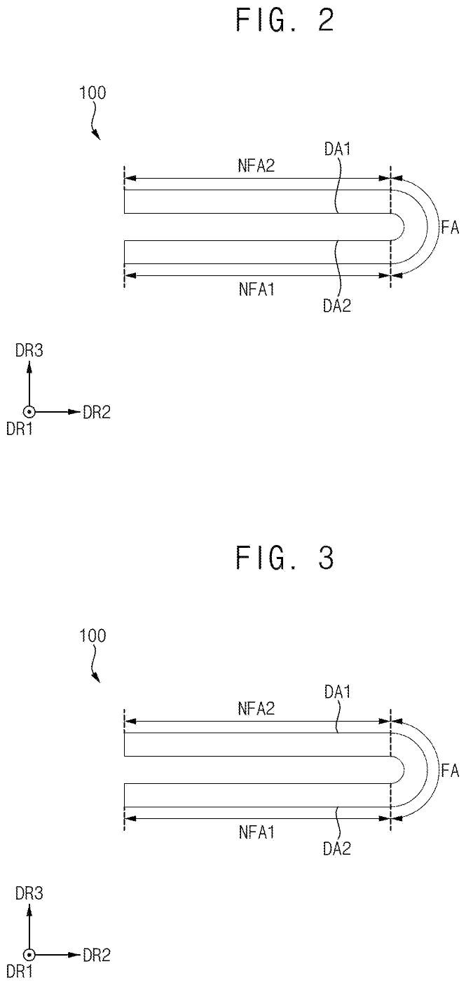

FIG. 1 is a perspective view illustrating a display device according to an embodiment of the present invention FIG. 2 is a side view illustrating an example of a folded state of the display device of FIG. 1. FIG. 3 is a side view illustrating an example of a folded state of the display device of FIG. 1.

Referring to FIGS. 1, 2 and 3, a display device 100 according to an embodiment of the present invention may include a display area DA and a peripheral area PA. The display area DA may be an area that generates an image, and the peripheral area PA may be an area that does not generate an image. The peripheral area PA may be located adjacent to the display area DA. For example, the peripheral area PA may entirely surround the display area DA.

In this specification, a plane may be defined in a first direction DR1 and a second direction DR2. For example, the second direction DR2 may be substantially perpendicular to the first direction DR1. In addition, a third direction DR3 may be substantially perpendicular to the plane.

The display device 100 includes a foldable area FA and first and second non-folding areas NFA1 and NFA2. The foldable area FA can be bent by an external force so that the display device 100 can be folded, and the first and second non-folding areas NFA1 and NFA2 do not fold and are adjacent to at least one side of the foldable area FA. The foldable area FA and the first and second non-folding areas NFA1 and NFA2 may at least overlap the display area DA. For example, the foldable area FA may have a folding axis extending along the first direction DR1.

The display area DA may be divided into a first display area DA1 and a second display area DA2 that are adjacent to each other in the second direction DR2 that intersects the first direction DR1. For example, the second direction DR2 may intersect the first direction DR1. The first display area DA1 and the second display area DA2 may be continuously connected to each other to substantially form one display area DA. For example, when the display area DA is folded along the folding axis as shown in FIG. 2, the display device may have an in-folded structure so that the first display area DA1 and the second display area DA2 face each other. In addition, when the display device area DA is folded along the folding axis as shown in FIG. 3, the display device may have an out-folded structure in which the display area DA is disposed on the outside. For example, in this case, the first display area DA1 and the second display area DA2 face away from each other.

The display device 100 according to an embodiment of the present invention is not limited to including one foldable area FA. For example, the display device 100 may be folded multiple times or may have a plurality of foldable areas FA to implement a rollable display device 100.

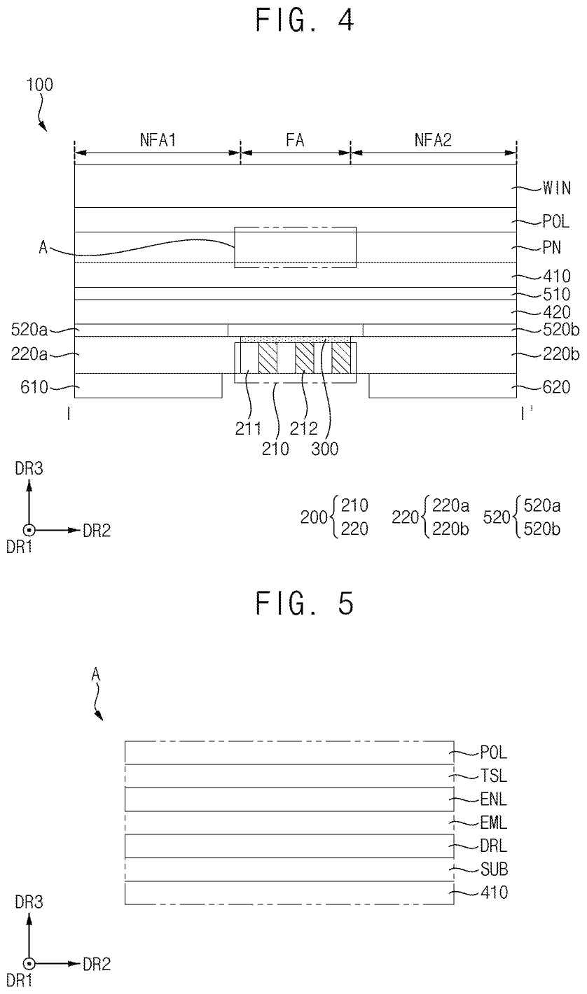

FIG. 4 is a cross-sectional view taken along line I-I′ line of FIG. 1. FIG. 5 is an enlarged cross-sectional view of area A of FIG. 4. For example, FIG. 4 may show the display device 100 of FIG. 1 in an unfolded state. In addition, FIG. 5 is an enlarged cross-sectional view of a part of a display panel PN of FIG. 4.

Referring to FIG. 4, the display device 100 according to an embodiment of the present invention may include a window member WN, a polarizing member POL, a display panel PN, a polymer film layer 410, a first adhesive member 510, a barrier member 420, a second adhesive member 520, a base film 300, a support member 200 including a first segmental elements 211, a second segmental elements 212, and a flat part 220, a first heat dissipation member 610 and a second heat dissipation member 620.

Referring to FIG. 5, the display panel PN may include a substrate SUB, a circuit driving layer DRL disposed on the substrate SUB, an emission layer EML disposed on the circuit driving layer DRL, and an encapsulation layer ENL disposed on the emission layer EML, and a touch layer TSL disposed on the encapsulation layer ENL.

The substrate SUB may be a flexible substrate including a flexible molecular material such as polyimide. As the substrate SUB is a flexible substrate, the display panel PN may be bent, folded, or rolled.

The circuit driving layer DRL may be disposed on the substrate SUB. The circuit driving layer DRL may include a circuit that drives the light emitting layer EML. The circuit driving layer DRL may include a plurality of thin film transistors.

The light emitting layer EML may be disposed on the circuit driving layer DRL. The light emitting layer EML may include an organic light emitting layer. The light emitting layer EML can emit light with different levels of brightness depending on the driving signal transmitted from the circuit driving layer DRL.

The encapsulation layer ENL may be disposed on the light emitting layer EML. For example, the encapsulation layer ENL may include an inorganic layer or a stacked layer of an inorganic layer and an organic layer.

The touch layer TSL may be disposed on the encapsulation layer ENL. The touch layer TSL may be a layer that recognizes touch pressure and can perform the function of a touch member. For example, the touch layer TSL may perform a function in response to a touch input such as a body part or an object. The touch layer TSL may include a plurality of sensing areas and a plurality of sensing electrodes.

The polarizing member POL may be disposed on the display panel PN. As the display device 100 includes a foldable area FA, the first non-folding area NFA1 and the second non-folding area NFA2, the display panel PN may also include the foldable area FA, the first non-folding area NFA1 and the second non-folding area NFA2. The display panel PN may include a plurality of sub-pixels that generate light. The polarizing member POL may block external light incident on the display panel PN from the outside.

The window member WN may be disposed on the polarizing member POL. The window member WN may have a transparent part corresponding to the display area DA. For example, the window member WN may include a polymer material, a thin glass film, and the like to enable bending. These may be used alone or in combination with each other.

The polymer film layer 410 may be disposed under the display panel PN. The polymer film layer 410 may include a polymer film. For example, the polymer film layer 410 may include polyimide PI, polyethylene terephthalate PET, polycarbonate PC, polyethylene PE, polypropylene PP, poly sulfone PSF, and poly methyl methacrylate PMMA, tri acetyl cellulose TAC, cycloolefin polymer COP, and the like. These may be used alone or in combination with each other.

The barrier member 420 may be disposed on the polymer film layer 410. For example, the barrier member 420 may be disposed under the polymer film layer 410. The first adhesive member 510 may be disposed between the polymer film layer 410 and the barrier member 420. For example, the first adhesive member 510 may attach the polymer film layer 410 and the barrier member 420 to each other.

The second adhesive member 520, the base film 300, the support member 200, the first heat dissipation member 610 and the second heat dissipation member 620 may be disposed under the barrier member 420. The barrier member 420 may include an elastic material whose length is variable as the display panel PN is folded or unfolded.

The support member 200 may be disposed on the barrier member 420. For example, the support member 200 may be disposed under the barrier member 420. In an embodiment of the present invention the support member 200 may include the flat part 220, which overlaps the first non-folding area NFA1 and second non-folding area NFA2, and a plurality of segmental elements 210 overlapping the foldable area FA. The flat part 220 may include a first flat part 220a, which overlaps the first non-folding area NFA1, and a second flat part 220b, which overlaps the second non-folding area NFA2.

In an embodiment of the present invention the support member 200 may include metal or fiber reinforced plastic. Examples of the metal may include steel used stainless (SUS), invar, aluminum, iron chromium, carbon, nickel, silicon, manganese, and molybdenum, and the like. These may be used alone or in combination with each other.

The fiber reinforced plastic may include glass fiber reinforced plastic, carbon fiber reinforced plastic, and the like. These may be used alone or in combination with each other. The plurality of segmental elements 210 may be adjacent to the flat part 220 in the second direction DR2. For example, the plurality of segmental elements 210 may be disposed between the first flat part 220a and the second flat part 220b. The plurality of segmental elements 210 overlapping the foldable area FA may include the first segmental elements 211 and the second segmental elements 212.

As shown in FIG. 4, when the display device 100 is unfolded, each of the first segmental elements 211 may be adjacent to the second segmental elements 212 in the second direction DR2. For example, each of the first segmental elements 211 may contact a second segmental element 212 in the second direction DR2 toward the first flat part 220a, and may contact another second segmental element 212 in the second direction DR2 toward the second flat part 220b.

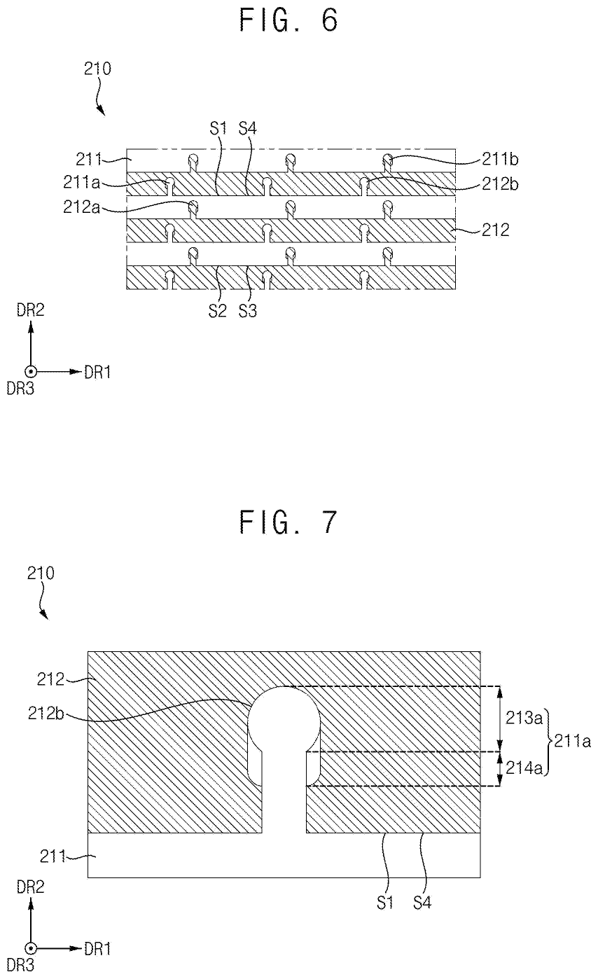

Hereinafter, the first segmental elements 211 and the second segmental elements 212 will be explained in more detail in FIG. 6.

In addition, the conventional support member, according to a comparative example, disposed on the bottom of the display panel PN of the display device 100 and overlapping the foldable area FA included a lattice part. In the lattice part, flexible metal rods are arranged regularly and there is a boundary area of a hole between the metal rods, so the lattice part may easily be deformed in a folded state and impact resistance may be reduced. As described above, according to an embodiment of the present invention since the display device 100 may include the support member 200 including the first segmental elements 211 and the second segmental elements 212, the impact resistance may be increased compared to the case including the conventional support member, according to a comparative example, including the lattice part which is disposed on the bottom of the display panel PN and overlaps the foldable area FA.

The base film 300 may be disposed on the barrier member 420. For example, the base film 300 may be disposed under the barrier member 420. In addition, the base film 300 may be disposed adjacent to the first segmental elements 211 and the second segmental elements 212 in the third direction DR3. For example, the base film 300 may be disposed adjacent to a surface of the first segmental elements 211 and the second segmental elements 212 in the third direction DR3. For example, the base film 300 may be disposed on the segmental elements 210. Accordingly, fatigue durability may be increased by preventing a crease and/or indentation from occurring in the foldable area FA of the display device 100. In addition, it may be possible to prevent foreign matters or particles from entering from the outside.

In an embodiment of the present invention the base film 300 may include a silicon-based material.

The second adhesive member 520 may be disposed between the barrier member 420 and the flat part 220. The second adhesive member 520 may include a third adhesive member 520a and a fourth adhesive member 520b that are spaced apart from each other. For example, the third adhesive member 520a and the fourth adhesive member 520b may be spaced apart from each other in the second direction DR2. For example, each of the third adhesive member 520a and the fourth adhesive member 520b might not overlap the foldable area FA. However, embodiments of the present invention are not limited thereto. The third adhesive member 520a may attach the barrier member 420 and the first flat part 220a to each other, and the fourth adhesive member 520b may attach the barrier member 420 and the second flat part 220b to each other.

For example, the second adhesive member 520 may include an optical clear adhesive (OCA), a pressure sensitive adhesive (PSA), a photocurable resin, a thermosetting resin, and the like. These may be used alone or in combination with each other.

The first heat dissipation member 610 and the second heat dissipation member 620 may be disposed on the flat part 220. For example, the first heat dissipation member 610 and the second heat dissipation member 620 may be disposed under the flat part 220. The first heat dissipation member 610 and the first flat part 220a may be located adjacent to each other. The second heat dissipation member 620 and the second flat part 220b may be located adjacent to each other.

FIG. 6 is an enlarged plan view of a plurality of segmental elements of FIG. 4.

Referring to FIG. 6, in an embodiment of the present invention each of the first segmental elements 211 may include a plurality of first protrusions 211a protruding from a first surface S1 of each of the first segmental elements 211 in the second direction DR2 and a plurality of first depressions 211b depressed from a second surface S2 that is opposite to the first surface S1 of each of the first segmental elements 211. In addition, each of the second segmental elements 212 may include a plurality of second protrusions 212a protruding from a first surface S3 of each of the second segmental elements 212 in the second direction DR2 and a plurality of second depressions 212b depressed from a second surface S4 that is opposite to the first surface S3 of each of the second segmental elements 212.

In an embodiment of the present invention the first protrusions 211a of a first segmental element 211 of the first segmental elements 211 may be male and female coupled to the second depressions 212b of an adjacent second segmental element 212, respectively, and the first depressions 211b of the first segmental element 211 may be male and female coupled to the second protrusions 212a of another adjacent second segmental element 212, respectively. For example, the first protrusions 211a may be inserted into the second depressions 212b, and the second protrusions 212a may be inserted into the first depressions 211b. In addition, the second protrusions 212a of a second segmental element 212 of the second segmental elements 212 may be male and female coupled to the first depressions 211b of an adjacent first segmental element 211, respectively, and the second depressions 212b of the second segmental element 212 may be male and female coupled to the first protrusions 211a of another adjacent first segmental element 211, respectively. At this time, the first surface S1 of each of the first segmental elements 211 may face the second surface S4 of the adjacent second segmental element 212. In addition, the second surface S2 of each of the first segmental elements 211 may face the first surface S3 of the adjacent second segmental element 212.

In an embodiment of the present invention each of the first segmental elements 211 and the second segmental elements 212 may extend in the first direction DR1 intersecting the second direction DR2.

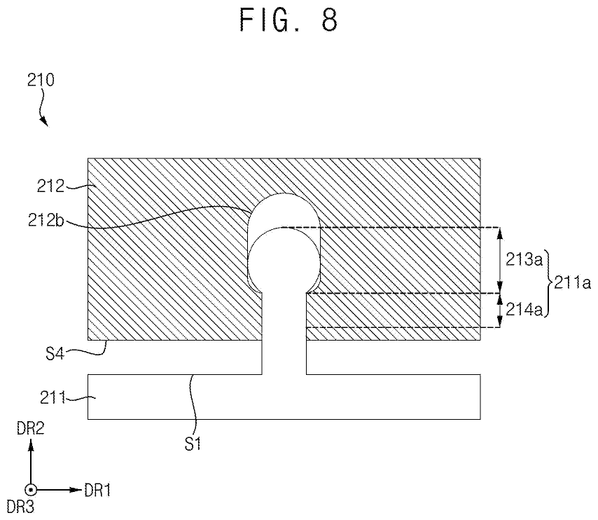

FIG. 7 is a plan view illustrating an example of a plurality of segmental elements of FIG. 4 in an unfolded state of the display device of FIG. 4. FIG. 8 is a plan view illustrating an example of a plurality of segmental elements of FIG. 4 in a folded state of the display device of FIG. 4.

Referring to FIGS. 6, 7 and 8, as described above, each of the first segmental elements 211 may include a first protrusion 211a and a first depression 211b, and each of the second segmental elements 212 may include a second protrusion 212a and a second depression 212b.

In an embodiment of the present invention the first protrusion 211a may include a first neck end 214a and a first end 213a. The first neck end 214a may be spaced apart from the first surface S1 of the first segmental element 211, and the first end 213a may extend from the first neck end 214a in the second direction DR2. In addition, the second protrusion 212a may include substantially the same structure and shape as the first protrusion 211a. For example, the second protrusion 212a may include a second neck end and a second end. The second neck end may be spaced apart from the first surface S3 of the second segmental element 212, and the second end may extend from the second neck end in the second direction DR2. For example, the second neck end may have a similar or same form, shape, and/or configuration as that of the first neck end 214a, and the second end may have a similar or same form, shape, and/or configuration as that of the first end 213a.

In an embodiment of the present invention the first surface S1 of each of the first segmental elements 211 may contact or be spaced apart from the second surface S4 of the adjacent second segmental element 212. For example, as shown in FIG. 7, when the display device (for example, the display device 100 of FIG. 1) is unfolded, the first surface S1 of each of the first segmental elements 211 may contact the second surface S4 of the adjacent second segmental element 212. In addition, as shown in FIG. 8, when the display device is folded, the first surface S1 of each of the first segmental elements 211 may be apart from the second surface S4 of the adjacent second segmental element 212. In addition, the second surface S2 of the each of the first segmental elements 211 may contact or be spaced apart from the first surface S3 of the adjacent second segmental element 212.

At this time, as shown in FIG. 7, when the display device is unfolded, the first neck end 214a may be a part spaced apart from the second segmental element 212 that is adjacent to each of the first protrusions 211a of the first segmental elements 211 and overlapping the adjacent second segmental element 212 in the first direction DR1. In addition, the second neck end may be a part spaced apart from the first segmental element 211 that is adjacent to each of the second protrusions 212a of the second segmental elements 212 and overlapping the adjacent first element 211 in the first direction DR1.

In contrast, as shown in FIG. 8, when the display device is folded, the first neck end 214a may be a part in contact with the second segmental element 212 that is adjacent to each of the first protrusions 211a of the first segmental elements 211 and overlapping the adjacent second segmental element 212 in the first direction DR1. In addition, the second neck end may be a part in contact with the first segmental element 211 that is adjacent to each of the second protrusions 212a of the second segmental element 212 and overlapping the adjacent first segmental element 211 in first direction DR1.

A length T of the first neck end 214a when the display device is unfolded may be the same as the length T of the first neck end 214a when the display device is folded. In addition, a length T of the second neck end when the display device is unfolded may be the same as the length T of the second neck end when the display device is folded.

In an embodiment of the present invention as shown in FIG. 7 and FIG. 8, the first end 213a of each of the first protrusions 211a may have a circular shape, and a part of each of the second depressions 212b in contact with the first end 213a may have a rounded shape. In addition, the second end of each of the second protrusions 212a may have a circular shape, and a part of each of the first depressions 211b in contact with the second end may have a rounded shape.

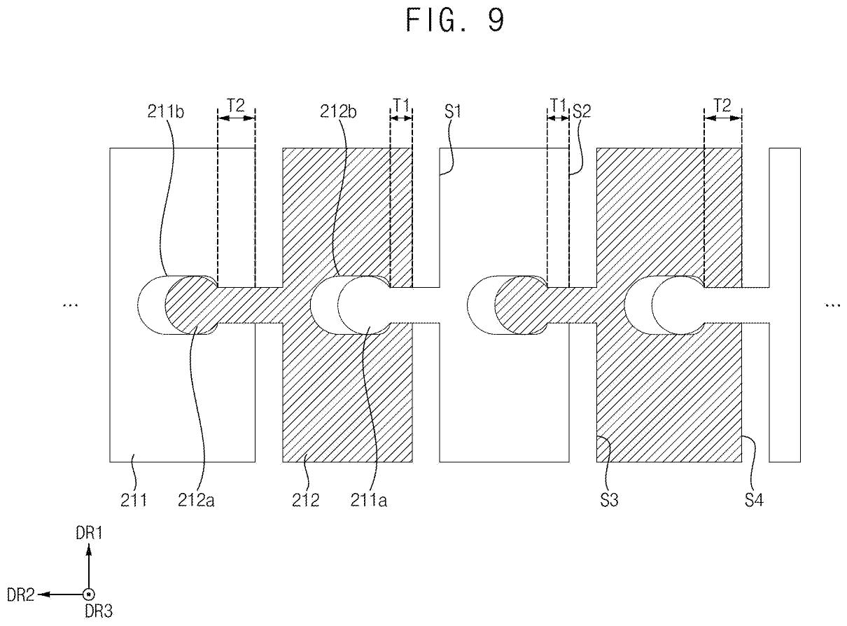

FIG. 9 is a plan view illustrating an example of a plurality of segmental elements of FIG. 4 in a folded state of the display device of FIG. 4.

Referring to FIG. 9, a length of each of the first and second protrusions 211a and 212a of a plurality of segmental elements 210 may be different in second direction DR2 and a direction opposite to the second direction DR2. At this time, the length of each of the first and the second protrusions 211a and 212a of a plurality of segmental elements 210 may have the same length as each other in the first direction DR1 and a direction opposite to the first direction DR1.

A length, in the second direction DR2, of the first protrusion 211a of the first segmental element 211 overlapping a center of the foldable area FA and a length, in the second direction DR2, of the first protrusion 211a of the first segmental element 211 overlapping an edge of the foldable area FA may be different from each other.

In an embodiment of the present invention the length, in the second direction DR2, of the first protrusion 211a of the first segmental element 211 overlapping the center of the foldable area FA may be smaller than the length, in the second direction DR2, of the first protrusion 211a of the first segmental element 211 overlapping the edge of the foldable area FA.

In addition, a length, in the second direction DR2, of the second protrusion 212a of the second segmental element 212 overlapping the center of the foldable area FA and a length, in the second direction DR2, of the second protrusion 212a of the second segmental element 212 overlapping the edge of the foldable area FA may be different from each other.

In an embodiment of the present invention the length, in the second direction DR2, of the second protrusions 212a of the second segmental element 212 overlapping the center of the foldable area FA may be smaller than the length, in the second direction DR2, of the second protrusion 212a of the second segmental element 212 overlapping the edge of the foldable area FA.

The length T, in the second direction DR2, of each of the first neck end 214a and the second neck end overlapping the center of the foldable area FA and the length T, in the second direction DR2, of each of the first neck end 214a and the second neck end overlapping the edge of the foldable area FA may be different from each other.

In an embodiment of the present invention a first length T1, in the second direction DR2, of each of the first neck end 214a and the second neck end overlapping the center of the foldable area FA may be smaller than a second length T2, in the second direction DR2, of each of the first neck end 214a and second neck end overlapping the edge of the foldable area FA.

In addition, when a side of the display device 100 in the foldable area FA is curved as shown in FIG. 2 and FIG. 3 when the display device 100 is folded, the degree of bending of the curve may be strain rate. A total strain rate may refer to the degree to which the display device 100 is deformed throughout the foldable area FA when the display device 100 is folded. When the display device 100 is folded, the strain rate of the center of the foldable area FA and the edge of the foldable area FA may be different from each other. Typically, because the center of the foldable area FA may be more bent than the edge of the foldable area FA, the strain rate of the center of foldable area FA may be larger than the strain rate of the edge of the foldable area FA.

If the strain rate of the center of the foldable area FA is large, plastic deformation may increase and fold marks may increase in foldable area FA of the display device 100. If the strain rate of the center of the foldable area FA is small, the plastic deformation may decrease and the fold marks may decrease in the foldable area FA of the display device 100.

As describe above, the length T of each of the first neck end 214a and the second neck end overlapping the center of the foldable area FA in the second direction DR2 may be smaller than the length T of each of the first neck end 214a and the second neck end overlapping the edge of the foldable area FA in the second direction DR2. Accordingly, impact resistance may be increased by decreasing the strain rate of the center of the foldable area FA while maintaining the total strain rate of the display device 100. In addition, the fold marks in the foldable area FA of the display device 100 may decrease by reducing the plastic deformation of support member 200 at the center of the foldable area FA.

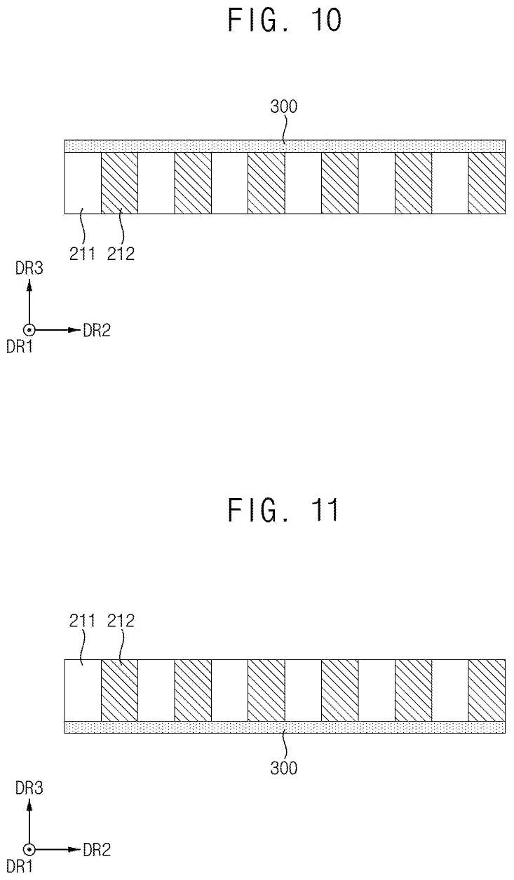

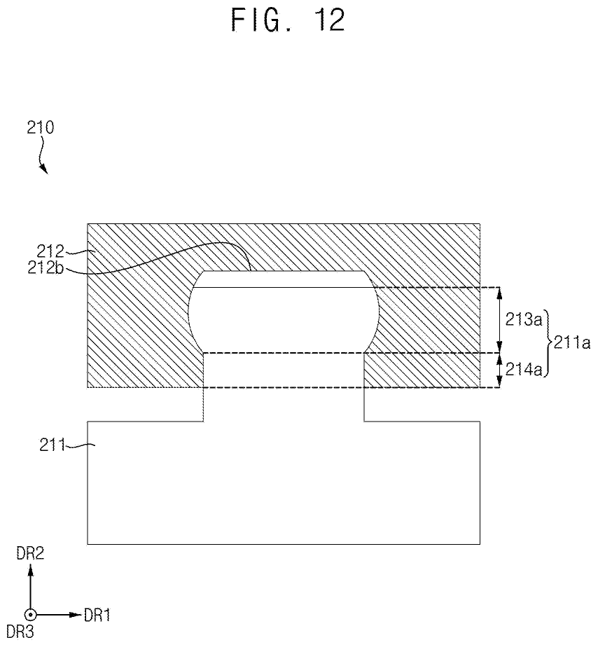

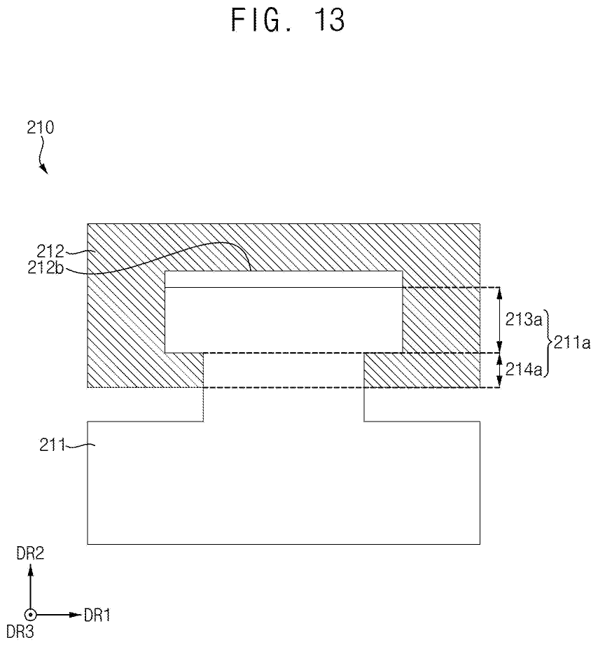

FIG. 10 is a cross-sectional view illustrating an example of first segmental elements, second segmental elements and a base film of FIG. 4. FIG. 11 is a cross-sectional view illustrating another example of first segmental elements and second segmental elements and a base film of FIG. 4.

Referring to FIG. 10, in an embodiment of the present invention the base film 300 may be disposed on the first segmental elements 211 and the second segmental elements 212 in the third direction DR3. For example, the base film 300 may contact first surfaces of the first segmental elements 211 and first surfaces of the second segmental elements 212 that face the display panel (for example, the display panel PN of FIG. 4). For example, the first surfaces of the first segmental elements 211 and the first surfaces of the second segmental elements 212 may be coplanar or substantially coplanar.

Referring to FIG. 11, in an embodiment, the base film 300 may be disposed on second surfaces of the first segmental elements 211, which are opposite to the first surfaces in the third direction DR3, and second surfaces of the second segmental elements 212, which are opposite to the first surfaces in the third direction DR3. For example, the base film 300 may contact the second surfaces of the first segmental elements 211 and the second surfaces of the second segmental elements 212. For example, the second surfaces of the first segmental elements 211 and the second surfaces of the second segmental elements 212 may be coplanar or substantially coplanar.

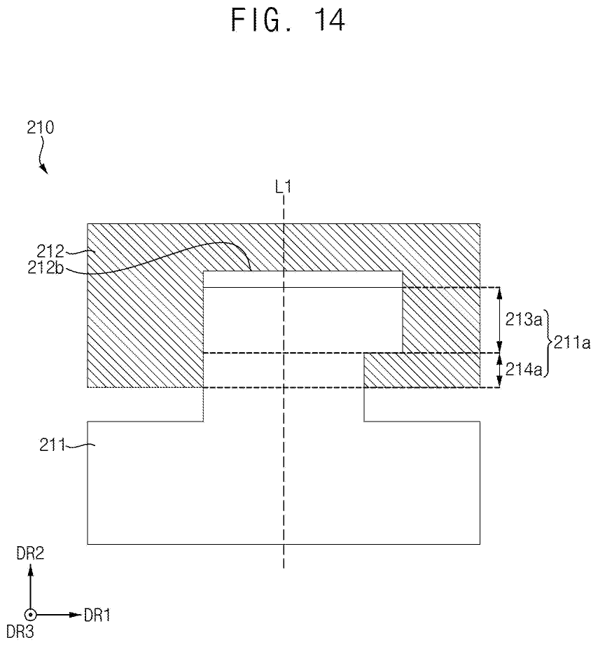

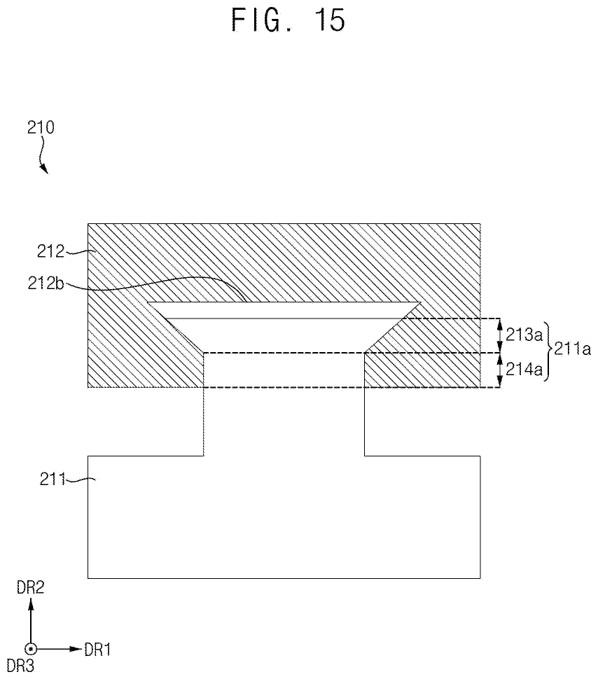

FIG. 12 is a plan view illustrating an example of first segmental elements and second segmental elements of FIG. 4. FIG. 13 is a plan view illustrating an example of first segmental elements and second segmental elements of FIG. 4. FIG. 14 is a plan view illustrating an example of first segmental elements and second segmental elements of FIG. 4. FIG. 15 is a plan view illustrating an example of first segmental elements and second segmental elements of FIG. 4. For example, FIGS. 12 to 15 are plan views illustrating the first segmental elements and the second segmental elements.

Referring to FIGS. 12, 13, 14, and 15, the first end 213a of the first protrusion 211a may include various shapes. In addition, a part of the second depression 212b, which is in contact with the first end 213a, may include a straight line or a curved line on a plane. Although, the second end of the second protrusion 212a may have the same or substantially the same shape and structure as the first end 213a of the first protrusion 211a. In addition, the first depression 211b may have the same or substantially the same shape and structure as the second depression 212b.

As shown in FIG. 12, in an embodiment of the present invention the first end 213a of the first protrusion 211a may have a circular planar shape, and the part of the second depression 212b in contact with the first end 213a may have a rounded planar shape. In addition, the second end of the second protrusion 212a may have a circular planar shape and the part of the first depression 211b in contact with the second end may have a rounded planar shape.

In addition, the first end 213a and the second end, of each of the first protrusion 211a and second protrusion 212b, respectively, and the first and the second depressions 211b and 212b may have various polygonal planar shapes.

As shown in FIG. 13, the first end 213a of the first protrusion 211a may have a rectangular planar shape, and the part of the second depression 212b in contact with the first end 213a may have rectangular planar shape. In addition, the second end of the second protrusion 212a may have a rectangular planar shape, and the part of the first depression 211b in contact with the second end may have a rectangular planar shape. Accordingly, when the display device is repeatedly folded, noise generated due to friction between the plurality of adjacent segmental elements 210 may be reduced.

As shown in FIG. 14, in an embodiment of the present invention the first end 213a of the first protrusion 211a may have a rectangular shape which is asymmetrical with respect to an imaginary center line L1 passing through a center of the first neck end 214a in the second direction DR2. For example, a center of the first end 213a may be misaligned with the imaginary center line L1. In addition, the part of the second depression 212b in contact with the first end 213a may have the asymmetrical rectangular shape.

The second end of the second protrusion 212a may have a rectangular shape which is asymmetrical with respect to an imaginary center line passing through a center of the second neck end. In addition, the part of the first depression 211b in contact with the second end may have the asymmetrical rectangular shape. The imaginary center line passing through the center of the second neck end may have the same or substantially the same position as the imaginary center line L1 shown in FIG. 14.

As shown in FIG. 15, the first end 213a of the first protrusion 211a may have a trapezoid planar shape, and the part of the second depression 212b in contact with the first end 213a may have a trapezoid planar shape. In addition, the second end of the second protrusion 212a may have a trapezoid planar shape, and the part of the first depression 211b in contact with the second end may have a trapezoid planar shape.

The display devices according to some embodiments of the present invention may be applied to a display device included in, for example, a computer, a notebook, a mobile phone, a smartphone, a smart pad, a PMP, a PDA, an MP3 player, or the like.

While the present invention has been described with reference to embodiments thereof, it will be understood by those of ordinary skill in the art that various changes in form and details may be made thereto without departing from the spirit and scope of the present invention.

What is claimed is:

1. A display device comprising:
a display panel including a non-folding area and a foldable area adjacent to the non-folding area;
a support member disposed on the display panel and including:
a flat part overlapping the non-folding area;
a plurality of first segmental elements overlapping the foldable area; and
a plurality of second segmental elements overlapping the foldable area and respectively coupled to the plurality of first segmental elements; and
a base film disposed on one surface of each of the plurality of first segmental elements and the plurality of second segmental elements.

2. The display device of claim 1, wherein each of the plurality of first segmental elements includes:
a plurality of first protrusions protruding from a first surface of each of the plurality of first segmental elements; and
a plurality of first depressions depressed from a second surface opposite to the first surface of each of the plurality of first segmental elements; and
wherein each of the plurality of second segmental elements includes:
a plurality of second protrusions protruding from a first surface of each of the plurality of second segmental elements; and
a plurality of second depressions depressed from a second surface of each of the plurality of second segmental elements opposite to the first surface.

3. The display device of claim 2, wherein the plurality of first segmental elements and the plurality of second segmental elements are alternately arranged.

4. The display device of claim 2, wherein the first protrusions of a first segmental element among the plurality of first segmental elements are coupled to the second depressions of an adjacent second segmental element of the plurality of second segmental elements, respectively, and
wherein the first depressions of the first segmental element are coupled to the second protrusions of another adjacent second segmental element of the plurality of second segmental elements respectively.

5. The display device of claim 2, wherein an end of each of the first protrusions and the second protrusions has a circular shape, and a part of each of the first depressions and the second depressions respectively contacting the end of each of the first protrusions and the second protrusions has a rounded shape.

6. The display device of claim 2, wherein an end of each of the first protrusions and the second protrusions has a rectangular shape, and a part of each of the first depressions and the second depressions respectively contacting the end of each of the first protrusions and second protrusions has a rectangular shape.

7. The display device of claim 6, wherein the end of each of the first protrusions and the second protrusions is asymmetrical with respect to a center line passing through centers of the corresponding first protrusions and second protrusions.

8. The display device of claim 1, wherein the base film includes a silicon-based material.

9. The display device of claim 1, wherein the base film contacts first surfaces of the plurality of first segmental elements and first surfaces of the plurality of second segmental elements facing the display panel.

10. The display device of claim 1, wherein the base film contacts a second surface opposite to a first surface of each of the plurality of first segmental elements and the plurality of second segmental elements wherein the first surface faces the display panel.

11. The display device of claim 1, the support member includes metal or fiber reinforced plastic.

12. A display device comprising:
a display panel including a non-folding area and a foldable area adjacent to the non-folding area;
a support member disposed under the display panel and including:
a flat part overlapping the non-folding area;
a plurality of first segmental elements overlapping the foldable area and including a plurality of first protrusions protruding from first surfaces of the plurality of first segmental elements and having different lengths from each other in a first direction;
and a plurality of second segmental elements overlapping the foldable area and alternately arranged with the plurality of first segmental elements along the first direction, wherein the plurality of second segmental elements includes a plurality of second protrusions protruding from a first surface of the plurality of second segmental elements and having different lengths from each other in a first direction wherein the plurality of second segmental elements are respectively coupled to the plurality of first segmental elements; and
a base film disposed on each of the plurality of first segmental elements and the plurality of second segmental elements.

13. The display device of claim 12, wherein each of the plurality of first segmental elements further includes a plurality of first depressions depressed from a second surface opposite to the first surface of each of the plurality of first segmental elements; and
wherein each of the plurality of second segmental elements further includes a plurality of second depressions depressed from a second surface opposite to the first surface of each of the plurality of second segmental elements.

14. The display device of claim 13, wherein the first protrusions of a first segmental element among the plurality of first segmental elements are male and female coupled to the second depressions of an adjacent second segmental element of the plurality of second segmental elements respectively, and
wherein the first depressions of the first segmental element are male and female coupled to the second protrusions of another adjacent second segmental element of the plurality of second segmental elements respectively.

15. The display device of claim 12, wherein a length, in the first direction of each of the first protrusions overlapping a center of the foldable area is smaller than a length, in the first direction of each of the first protrusions overlapping an edge of the foldable area, and
wherein a length, in the first direction of each of second protrusions overlapping the center of the foldable area is smaller than a length, in the first direction of each of the second protrusions overlapping the edge of the foldable area.

16. The display device of claim 13, wherein each of the first protrusions includes a first neck end and a first end, wherein the first neck end is spaced apart from the first surface of the corresponding first segmental element and the first end extends from the first neck end, and
wherein each of the second protrusions includes a second neck end and second end, wherein the second neck end is spaced from the first surface of the corresponding second segmental elements and the second end extends from the second neck end.

17. The display device of claim 16, wherein the first surface of each of the first segmental elements contacts or is spaced apart from the second surface of an adjacent second segmental element of the plurality of second segmental elements; and
wherein the second surface of each of the first segmental elements contacts or is spaced apart from the first surface of another adjacent second segmental element of the plurality of second segmental elements.

18. The display device of claim 17, wherein the first surface of each of the first segmental elements contacts the second surface of the adjacent second segmental element of the plurality of second segmental elements and the second surface of each of the first segmental elements contacts the first surface of the other adjacent second segmental element,
wherein the first neck end of each of the first segmental elements is spaced apart from the adjacent second segmental element and overlaps the adjacent second segmental element in a second direction intersecting the first direction; and
wherein the second neck end of each of the second segmental elements is spaced apart from an adjacent first segmental element and overlaps the adjacent first segmental element in the second direction intersecting the first direction.

19. The display device of claim 18, wherein a length, in the first direction of the first neck end overlapping a center of the foldable area is smaller than a length, in the first direction of the first neck end overlapping an edge of the foldable area, and
wherein a length, in the first direction of the second neck end overlapping the center of the foldable area is smaller than a length, in the first direction of the second neck end overlapping the edge of the foldable area.

20. The display device of claim 13, wherein each of the plurality of first segmental elements and the plurality of second segmental elements extends in a second direction intersecting the first direction.
